(19) United States
(12) Patent Application Publication
(10) Pub. No.: US 2011/0303644 A1
(43) Pub. Date: Dec. 15, 2011

(54) Methods for Plating Plastic Articles

(75) Inventor: Richard Macary, Wheaton, IL (US)

(73) Assignee: ARLINGTON PLATING COMPANY, Palatine, IL (US)

(21) Appl. No.: 12/796,791

(22) Filed: Jun. 9, 2010

(51) Int. Cl. H05K 3/46

(52) U.S. Cl. 216/83

(57) ABSTRACT

An improved method for plating and metallizing plastic articles is disclosed. A polymer is selected to mold a three-dimensional plastic article for use with miniaturized electronic devices. Patterns are structured onto the surface of the plastic article by means of laser direct structuring or by multi-shot injection molding. The patterns on the plastic article are activated with a colloidal palladium solution. The activated patterns are then plated with copper and nickel using electroless baths. Optionally, the patterns are flash gold plated to improve bonding, solderability and contact resistance.

### FIELD OF THE DISCLOSURE

Methods for plating or applying a thin layer of metal to plastic materials are disclosed. More particularly, methods for plating plastic-molded interconnect electronic devices are disclosed.

### BACKGROUND OF THE DISCLOSURE

Electronics are used in a variety of applications and have become an integral part of modern day life. Whether they are used in laptop computers, cellular phones, automobiles, medical devices, or the like, electronics have become essential tools for carrying out a wide range of daily activities. As time passes, consumers become increasingly more reliant on electronics and the demand for smaller, lighter and more reliable electronic devices increases. Accordingly, high-technology companies strive to fulfill these demands by developing smaller circuits and circuit components so as to construct thinner laptop computers, smaller cellular phones, smaller medical devices, and so on.

With the resulting advances in technology, the size and weight of electrical components, circuit boards, and the like, have significantly decreased. In particular, scientists and engineers have been able to provide smaller circuit boards with more compact circuit layouts by significantly manipulating and reducing the size of individual components. Insert molding methods also exist for molding electrical connections directly into components of plastics material, or the like. However, as devices become smaller and more compact, it is increasingly difficult to timely manufacture such circuitry and to simultaneously keep the cost of manufacturing relatively low. It is also an ongoing challenge to build smaller electronics without detrimentally effecting reliability and performance of the product.

Accordingly, there is a need for an improved method for integrating compact circuitry into miniaturized plastic components for the purposes of constructing lighter, smaller and more portable electronic devices. Furthermore, there is a need for a faster, easier, more reliable and cost effective method for miniaturizing and reducing component count. Moreover, there is a need for an improved method for plating or metallizing plastic articles, and constructing three-dimensional molded interconnect devices (MIDs).

While the following will be directed toward methods for plating plastic articles for compact electronics and related devices, it will be noted that this application and the methods disclosed herein are applicable to various fields beyond that of electronics, and more generally, can be applied to any related metallization of plastics material.

### SUMMARY OF THE DISCLOSURE

In satisfaction of the aforenoted needs, improved methods for plating plastic articles are disclosed.

One disclosed method for plating patterns onto a plastic article includes the steps of etching the plastic article, activating the patterns on the plastic article, treating the plastic article to a chemical reduction bath, plating the patterns with an electroless copper bath, and plating the patterns with an electroless nickel bath.

In a refinement, the plastic article is rinsed after each step.

In another refinement, the plastic article is chrome etched.

In another refinement, the plastic article is treated to each of the electroless copper plating and electroless nickel plating twice. In a related refinement, the copper plating is approximately 50-250 micro inches in thickness and the nickel plating is approximately 30-100 micro inches in thickness.

In another refinement, the plastic article is additionally flash gold plated. In a related refinement, the gold plating is approximately 5-8 micro inches in thickness.

Another method for plating a plastic article is disclosed. The method includes the steps of selecting a polymer for forming the plastic article, forming the plastic article, structuring a pattern on the plastic article, etching the plastic article, activating patterns onto the plastic article with colloidal palladium, treating the plastic article to a chemical reduction bath, plating the patterns with an electroless copper bath, and plating the patterns with an electroless nickel bath.

In a refinement, the polymer is selected from a group consisting of polycarbonate polymers, polycarbonate-acrylonitrile butadiene styrene blends, polybutylene terphtalate polymers, and liquid crystal polymers.

In another refinement, the patterns are structured on the plastic article by laser direct structuring.

In another refinement, the patterns on the plastic article are provided by multi-shot injection molding, wherein one of the shots injects palladium.

In another refinement, the plastic article is rinsed after each step.

In another refinement, the plastic article is chrome etched.

In another refinement, the plastic article is treated to each of the electroless copper plating and electroless nickel plating twice. In a related refinement, the copper plating is approximately 50-250 micro inches in thickness and the nickel plating is approximately 30-100 micro inches in thickness.

In yet another refinement, the plastic article is additionally flash gold plated. In a related refinement, the gold plating is approximately 5-8 micro inches in thickness.

These and other aspects and features of the disclosure will become more readily apparent upon reading the following detailed description when taken into conjunction with the accompanying drawings.

### BRIEF DESCRIPTION OF THE DRAWINGS

FIG. 1 is an exemplary flow chart of the overall method for forming an MID;

FIGS. 2A-2D illustrate perspective views of an exemplary MID made in accordance with this disclosure; and

FIG. 3 is an exemplary flow chart of an improved method for metallizing plastics material.

While the present disclosure is susceptible to various modifications, specific methods thereof have been outlined in the drawings and will be described below in detail. It should be understood, however, that there is no intention to limit the disclosure to the specific methods disclosed, but on the contrary, the intention is to cover all modifications and equivalents falling within the spirit and scope of the disclosure as defined by the appended claims.

### DETAILED DESCRIPTION OF THE DISCLOSURE

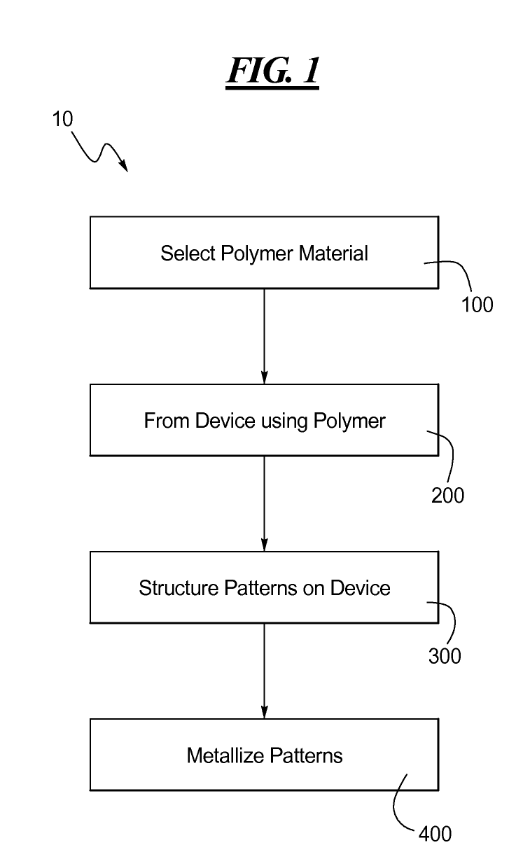

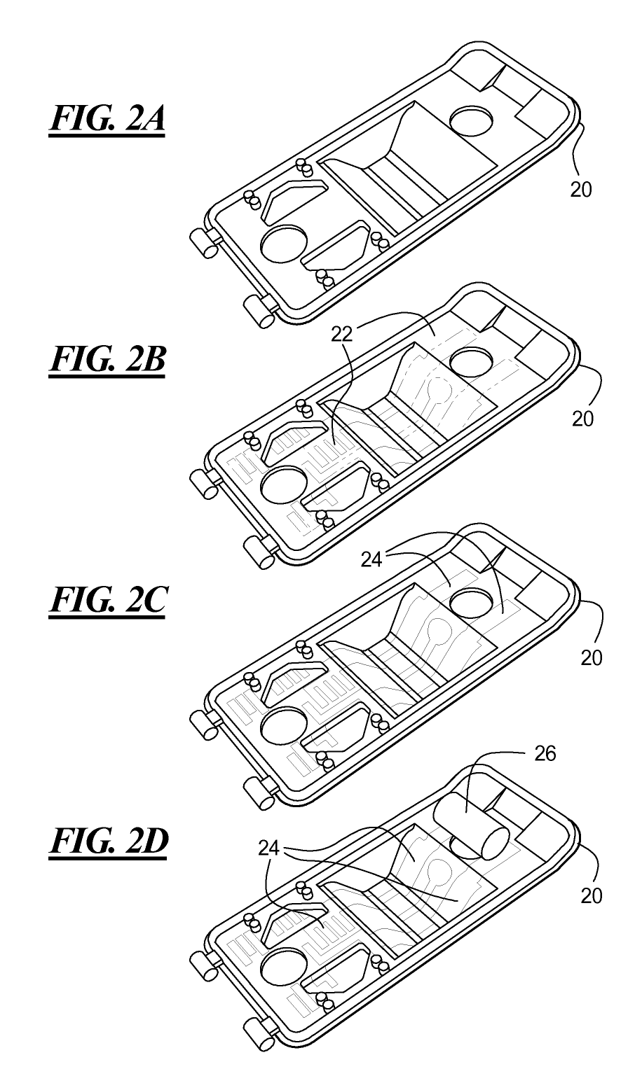

FIG. 1 illustrates the overall method 10 for plating a plastic article and providing a molded interconnect device (MID). FIGS. 2A-2D illustrates a plastic article or MID 20 that may be constructed in accordance with this disclosure.

In general, the method 10 of FIG. 1 may include an initial step 100 in which a material for forming the plastic article 20 is selected. For example, the plastic article 20 may include polycarbonate polymers, polycarbonate-acrylonitrile butadiene styrene blends, polybutylene terphtalate polymers, liquid crystal polymers, and the like. In a subsequent step 200, the polymer selected in step 100 may be used to form or mold the plastic article 20 of FIG. 2A. In step 300, patterns 22 corresponding to a desired circuit path may be structured or prepared for metallization. Moreover, patterns 22 to be plated with a metal may be structured onto the surface of the plastic article 20 as shown in FIG. 2B. Once the patterns 22 are structured in step 300, the patterns 22 may be treated and/or activated in step 400 so as to chemically bond with a metal and create the metallized MID 20 of FIG. 2C. After the metallization step 400, the MID 20 may be provided with additional circuit components 26, as shown in FIG. 2D, or any other connections required to complete the circuitry.

The structured patterns 22 may be structured on a surface of the device 20 using any suitable method known in the art. In particular, the initial polymer material selected in the first step 100 may include a reactive material that chemically responds to controlled stimuli. For instance, the polymer may include a laser-activatable thermoplastic doped with an additive which chemically and/or physically reacts to a laser. The reaction may form metallic nuclei, which serve as catalysts for reductive plating. The reaction may also create a microscopically rough surface to which a metal may firmly bond. Using the laser activation process, the method 10 of FIG. 1 may involve controlling the laser to selectively activate patterns 22, or only those desired portions of the surface of the device 20 for metallizing. Once activated, the patterns 22 of the device 20 may be rinsed and exposed to repeated chemical reduction or electroless baths which form a build-up of a selected metal only on the activated patterns 22 of the device 20. The build-up of metal on the activated patterns 22 during the metallization step 400 gradually forms a conductive circuit path 24 as shown on the surface of the MID 20 of FIG. 2C. The selected metal for plating may include copper, tin, silver, palladium, gold, and the like.

As an alternative to laser activation, the device 20 of FIG. 2B may be formed using double or multi-shot injection molding. More specifically, the device 20 may be molded using a selected polymer in a first shot, and in a subsequent shot, injection molded with a reactive material such as palladium, or the like. In such a case, the multi-shot injection may mold a plastic device 20 having palladium patterns 22 structured thereon. As in laser activation, a multi-shot molded device 20 may be rinsed and treated to several electroless baths during the metallization step 400 so as to create a bond between a selected metal and the structured patterns 22. For instance, the electroless baths may be configured to react only with the palladium to gradually form a conductive circuit path 24 along the structured patterns 22 on the surface of the device 20. Once the metallization step 400 is complete, the device 20 may be provided with circuit components 26, as shown in FIG. 2D, or any other connections required to complete the circuitry. As with the laser activation process, the selected metal for plating may similarly include copper, tin, silver, palladium, gold, and the like.

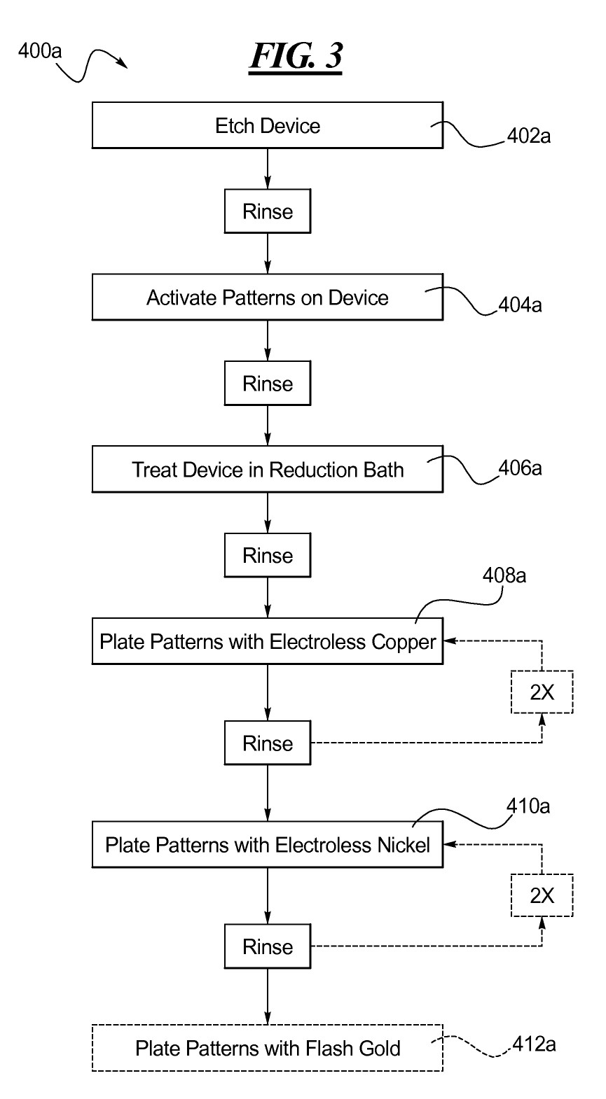

Turning now to FIG. 3, an exemplary method 400a for metallizing plastic articles is disclosed in more detail. A device 20 having patterns 22 structured thereon, either by laser activation or by multi-shot injection molding, may be etched in an initial step 402a using chrome baths or the like. An exemplary etching process 400a may be carried out in a bath having an etching temperature that can range from about 162 to about 167° F., for a time period ranging from about 11 to about 13 minutes and with the surface tension ranging from about 53 to about 57 dynes/cm³. After etching, a cold water rinse may be carried out for a short time period that can range from about five to about 10 seconds. Typically, a hot water rinse may then be carried out for about the same time period.

After the etching step 402a, the device 20 and the structured patterns 22 thereon may be activated in a subsequent step 404a. The activation step 404a may employ a colloidal palladium solution, or the like, to activate the patterns 22 for metal plating. An exemplary activation process 404a may be carried out over an immersion time ranging from about five to about seven minutes, at a temperature ranging from about 100 to about 110° F., in a colloidal palladium solution having a concentration ranging from about 1 to about 2 ounces per gallon (opg). A cold water rinse may follow in a subsequent step.

In a third metallization step 406a, the device 20 may be treated to a chemical reduction bath. An exemplary reduction step 406a may be carried out in a reduction bath having a temperature ranging from about 130 to about 140° F. for a time period ranging from about five to about seven minutes. One typical reducing agent may be formaldehyde at a concentration ranging from about 1 to about 2 ounces per gallon. A cold water rinse may follow in a subsequent step.

In step 408a of FIG. 3, the patterns 22 of the device 20 may be plated with a first metal, such as copper, using an electroless bath. Typically, the initial plating 408a may be a two-part process including an initial electroless strike followed by further deposition. In a strike bath having a temperature ranging from about 135 to about 145° F., a sodium hydroxide concentration ranging from about 3.5 to about 4.5 ounces per gallon, a copper sulfate concentration ranging from about 2.5 to about 3.5 ounces per gallon, a chelator concentration ranging from about 0.1 to about 0.2 ounces per gallon, the copper strike plating rate may vary in range from about 20 to about 24 micro inches per hour. The initial copper strike may be carried out for time period ranging from about three to about five minutes. The first plating step 408a may be continued under similar or different process conditions but for a longer time period. The deposition rate may typically increase to a rate ranging from about 80 to about 120 micro inches per hour. A cold rinse may follow in a subsequent step.

Finally, as shown in step 410a of FIG. 3, the device 20 may be plated with a second metal, such as nickel, using a second electroless bath and then rinsed. The initial electroless nickel strike step 410a may be carried out in a bath having a temperature ranging from about 100 to about 110° F., at a pH ranging from about 6 to about 7, a nickel sulfate solution having a concentration ranging from about 0.6 to about 0.8 ounces per gallon, and a sodium hypophosphite concentration ranging from about 2 to about 3 ounces per gallon. Such process conditions may create a plating rate ranging from about 100 to about 200 micro inches per hour. As in step 408a, the second plating step 410a may also be continued after the device 20. Thus, the electroless nickel step 410a may include a second deposition carried out in a bath having a higher temperature ranging from about 185 to about 195° F., at a lower pH ranging from about 4.5 to about 5.5, a nickel sulfate solution still having a concentration ranging from about 0.6 to about 0.8 ounces per gallon and a sodium hypophosphite concentration ranging from about 2 to about 3 ounces per gallon. Such process conditions may create a faster plating rate ranging from about 400 to about 500 micro inches per hour.

Additionally, the patterns 22 of the device 20 may be flash plated with a third metal, such as gold, in an optional step 412a to improve bonding, solderability and contact resistance. The typical range of thickness of copper plating formed using the method 400a of FIG. 3 may be approximately 50-250 micro inches while the typical range of thickness of nickel plating may be approximately 30-100 micro inches. The typical range of thickness of gold plating may be approximately 5-8 micro inches.

All the process conditions recited above including temperatures, time periods, concentrations, etc. may vary as will be apparent to those skilled in the art.

From the foregoing, it can be seen that the disclosure provides an improved method for plating or metallizing plastic articles. More specifically, the methods disclosed serve to facilitate miniaturization of electronic devices and components, eliminate costs associated with insert molding, eliminate costs associated with circuit boards, minimize component count and improve reliability. The disclosed methods are also ideal for metallizing patterned components in bulk, for example, in plating cylinders, on racks, or the like.

What is claimed is:

1. A method for selectively plating patterns onto a plastic article, comprising the steps of:
etching the plastic article;
activating the patterns on a surface of the plastic article;
treating the plastic article to a chemical reduction bath;
plating the patterns with an electroless copper bath; and
plating the patterns with an electroless nickel bath.

2. The method of claim 1, wherein the plastic article is rinsed at least once after each step.

3. The method of claim 1, wherein the plastic article is etched with chrome.

4. The method of claim 1, wherein the step of plating the patterns with an electroless copper bath is done twice before plating the patterns with an electroless nickel bath.

5. The method of claim 1 further comprising the step of plating the patterns with flash gold.

6. The method of claim 1, wherein the plastic article is three-dimensional.

7. The method of claim 1, wherein a plurality of plastic articles are metallized in a plating cylinder or on a rack.

8. The method of claim 1, wherein the electroless copper plating is approximately 50-250 micro-inches in thickness.

9. The method of claim 1, wherein the electroless nickel plating is approximately 30-100 micro-inches in thickness.

10. The method of claim 5, wherein the flash gold plating is approximately 5-8 micro-inches in thickness.

11. A method for plating a plastic article, comprising the steps of:
selecting a moldable polymer for forming the plastic article;
forming the plastic article;
structuring a pattern on the plastic article;
etching the plastic article;
activating patterns onto the plastic article with colloidal palladium;
treating the plastic article to a chemical reduction bath;
plating the patterns with an electroless copper bath; and
plating the patterns with an electroless nickel bath.

12. The method of claim 11, wherein the polymer is selected from a group consisting of:
polycarbonate polymers;
polycarbonate-acrylonitrile butadiene styrene blends;
polybutylene terphtalate polymers; and
liquid crystal polymers.

13. The method of claim 11, wherein the step of structuring patterns on the plastic article is done by laser direct structuring.

14. The method of claim 11, wherein the step of structuring patterns on the plastic article is done by multi-shot molding, at least one of the shots introducing palladium.

15. The method of claim 11, wherein the plastic article is rinsed at least once after each step.

16. The method of claim 11, wherein the plastic article is etched with chrome.

17. The method of claim 11, wherein the step of plating the patterns with an electroless copper bath is done twice before plating the patterns with an electroless nickel bath.

18. The method of claim 11 further comprising the step of plating the patterns with flash gold.

19. The method of claim 11, wherein the plastic article is three-dimensional.

20. The method of claim 11, wherein the electroless copper plating is approximately 50-250 micro-inches in thickness.

21. The method of claim 11, wherein the electroless nickel plating is approximately 30-100 micro-inches in thickness.

22. The method of claim 18, wherein the flash gold plating is approximately 5-8 micro-inches in thickness.
